(19) United States
(12) Patent Application Publication
(10) Pub. No.: US 2009/0084583 A1
(43) Pub. Date: Apr. 2, 2009

(54) MULTILAYER PRINTED WIRING BOARD AND METHOD FOR FABRICATION THEREOF

(76) Inventor: Yukihiro UENO, Mihara-shi (JP)

Correspondence Address: BIRCH STEWART KOLASCH & BIRCH, PO BOX 747, FALLS CHURCH, VA, 22040-0747, US

(21) Appl. No.: 12/122,211

(22) Filed: May 16, 2008

(30) Foreign Application Priority Data
Sep. 27, 2007 (JP) 2007-250675

(51) Int. Cl. H05K 1/02; H05K 3/00

(52) U.S. Cl. 174/254; 29/842

(57) ABSTRACT

Provided is a multilayer printed wiring board having a terminal portion of high quality. This multilayer printed wiring board has a flexible portion having flexibility, the flexible portion that can be bent when used, a rigid portion formed continuously with the flexible portion, the rigid portion having greater rigidity than the flexible portion, and a terminal portion formed continuously with the flexible portion at an end portion of the flexible portion. The rigid portion includes a rigid layer having insulation properties. The terminal portion includes an insulating layer formed of the same material as that for the rigid layer, the insulating layer having a conductive layer formed on the surface thereof, the conductive layer having a predetermined terminal pattern and serving as a connecting terminal.

This nonprovisional application claims priority under 35 U.S.C. § 119(a) on Patent Application No. 2007-250675 filed in Japan on Sep. 27, 2007, the entire contents of which are hereby incorporated by reference.

### BACKGROUND OF THE INVENTION

1. Field of the Invention

The present invention relates to multilayer printed wiring boards and a method for fabrication thereof.

2. Description of Related Art

Conventionally, a multilayer printed wiring board called a rigid-flexible wiring board is known. In general, the rigid-flexible wiring board (multilayer printed wiring board) is composed of a portion (hereinafter a “flexible portion”) that has flexibility and is used mainly as a cable, and a portion (hereinafter a “rigid portion”) having rigidity, the portion in which high-density wiring is possible and an operation such as mounting primarily of electronic parts is performed. This structure allows the rigid-flexible wiring board (multilayer printed wiring board) to be used with the flexible portion bent and thereby makes it possible to make effective use of a small mounting area, despite the fact that the electronic parts need to be mounted in a smaller mounting area with the miniaturization of electronic devices.

The abovementioned multilayer printed wiring board is used in compact electronic devices such as digital cameras, cellular telephones, and compact music players. Such a multilayer printed wiring board is disclosed, for example, in JP-A-H9-74252.

The conventional rigid-flexible wiring board (multilayer printed wiring board) is electrically connected to the other wiring board, an electronic device, and an electronic part as follows. In general, a terminal portion provided with a conductive layer having a predetermined terminal pattern is formed in an end portion of the flexible portion, and the terminal portion thus formed is brought into contact with a connector provided in the other wiring board, the electronic device, and the electronic part.

Here, the rigid-flexible wiring board (multilayer printed wiring board) is fabricated by using one of the following two fabrication processes. Of these two fabrication processes, one is a fabrication process A in which a rigid layer (insulating layer) and a conductive layer are formed in regions other than the region which will become the flexible portion of a film-like wiring substrate, and thereby forming the flexible portion and the rigid portion, and the other is a fabrication process B in which the rigid layer and the conductive layer are first formed all over the film-like wiring substrate, and the rigid layer and the conductive layer formed in the region which will become the flexible portion in a later process are then removed to expose the film-like wiring substrate in that region, and thereby forming the flexible portion and the rigid portion.

In either of these two fabrication processes, at the time of fabrication of the conventional rigid-flexible wiring board (multilayer printed wiring board), it is necessary to form a conductive layer having a terminal pattern in a predetermined region (a region corresponding to an end portion of the flexible portion) of the film-like wiring substrate before the formation process of the rigid layer and the conductive layer so as to form a terminal portion. As a result, in the conventional fabrication processes A and B, the following problems arise.

First of all, in the fabrication process A, an adhesive may now into a portion of the wiring substrate, the portion which will become the flexible portion, due to pressure applied at the time of formation of layers, or an etching solution used for forming a wiring pattern in a conductive layer may flow into a portion of the wiring substrate, the portion which will become the flexible portion. This unfavorably results in contamination of the terminal portion, and hence in poor connection. On the other hand, in the fabrication process B, since the wiring substrate is formed of an extremely thin material having flexibility, the wiring substrate may stick to the rigid layer due to pressure applied at the time of formation of layers. This unfavorably results in damage or deformation of the terminal portion that would occur when a portion of the wiring substrate, the portion which will become the flexible portion, is exposed, and hence in poor connection.

In addition, another problem is that, since the terminal portion is formed integrally on the flexible portion, it may be difficult to bring the terminal portion into contact with the connector depending on the film thickness or flexibility of the flexible portion. To solve this problem, the terminal portion may be reinforced with a reinforcing sheet. However, doing so unfavorably requires an extra process of forming a reinforcing sheet in the terminal portion.

### SUMMARY OF THE INVENTION

It is an object of the present invention to provide multilayer printed wiring boards provided with a terminal portion of high quality, and to provide methods for fabrication of such multilayer printed wiring boards.

To achieve the above object, according to one aspect of the present invention, a multilayer printed wiring board is provided with: a flexible portion having flexibility, the flexible portion that can be bent when used; a rigid portion formed continuously with the flexible portion, the rigid portion having greater rigidity than the flexible portion; and a terminal portion formed continuously with the flexible portion at an end portion of the flexible portion. Here, the rigid portion includes a rigid layer having insulation properties. The terminal portion includes an insulating layer formed of the same material as that for the rigid layer, the insulating layer having a conductive layer formed on the surface thereof, the conductive layer having a predetermined terminal pattern and serving as a connecting terminal.

Preferably, in the multilayer printed wiring board structured as described above, the terminal portion is constructed as a connecting terminal portion of an insertion type.

Preferably, in the multilayer printed wiring board structured as described above, the terminal portion includes a connecting portion for electrically connecting between the flexible portion and the conductive layer.

Preferably, in the multilayer printed wiring board structured as described above, the insulating layer of the terminal portion includes a plurality of insulating layers, and the conductive layer is formed on the surface of the outermost layer of the plurality of insulating layers.

Preferably, in the multilayer printed wiring board structured as described above, the terminal portion further includes a shielding layer.

Preferably, in the multilayer printed wiring board structured as described above, the flexible portion is constructed with a film-like wiring substrate, and the rigid portion is constructed by forming, in a predetermined region of the film-like wiring substrate, a plurality of wiring layers, each having a predetermined wiring pattern, and the rigid layer including a plurality of rigid layers.

Preferably, in the multilayer printed wiring board structured as described above, on one of the surfaces of the film-like wiring substrate, the insulating layer of the terminal portion includes a plurality of insulating layers, and the number of the insulating layers of the terminal portion is equal to the number of the rigid layers of the rigid portion.

Preferably, in the multilayer printed wiring board structured as described above, the insulating layer of the terminal portion is formed in a region of an end portion of the film-like wiring substrate, and at least part of the insulating layer of the terminal portion is made to project from an edge of the film-like wiring substrate as seen in a plan view.

According to another aspect of the present invention, a method for fabricating a multilayer printed wiring board is provided with: a step of forming an insulating layer and a conductive layer in a plurality of regions on a film-like wiring substrate, the plurality of regions being located at a predetermined distance from each other, the insulating layer including an outermost insulating layer having the conductive layer formed thereon; and a step of forming a terminal portion including the conductive layer by partially removing the conductive layer formed on the outermost insulating layer so as to make the conductive layer have a predetermined terminal pattern in at least one of the plurality of regions, and electrically connecting the conductive layer having the predetermined terminal pattern to the film-like wiring substrate.

Preferably, in the fabrication method described above, the plurality of regions include a first region and a second region, and the step of forming the terminal portion includes a step of partially removing the conductive layer formed on the outermost insulating layer located in the first region so as to make the conductive layer have a predetermined terminal pattern, and a step of forming a connecting portion for electrically connecting between the conductive layer and the film-like wiring substrate. Here, the fabrication method further includes a step of forming a circuit portion by partially removing the conductive layer located in the second region so as to make the conductive layer have a predetermined wiring pattern, the circuit portion including the conductive layer having the predetermined wiring pattern.

Preferably, in the fabrication method described above, the step of forming the insulating layer and the conductive layer includes a step of forming an insulating layer having an opening in a predetermined region and an conductive layer having an opening in a predetermined region on at least one of the surfaces of the film-like wiring substrate.

Preferably, in the fabrication method described above, the step of forming the insulating layer and the conductive layer includes a step of forming the insulating layer and the conductive layer almost all over at least one of the surfaces of the film-like wiring substrate, and the fabrication method further includes a step of removing part of the insulating layer and the conductive layer.

Preferably, in the fabrication method described above, the step of removing part of the insulating layer and the conductive layer includes a step of removing part of the insulating layer and the conductive layer forming the terminal portion.

Preferably, the fabrication method described above further includes a step of forming the multilayer printed wiring board into a final shape, such that the terminal portion is located in an end portion of the film-like wiring substrate as seen in a plan view.

According to the present invention, the terminal portion for establishing electrical connection with a connector of the other wiring board, an electronic device, an electronic part, or the like, is so formed as to include the insulating layer and the conductive layer. This makes it possible to form the terminal portion by making, after the formation of the insulating layer and the conductive layer, the conductive layer formed on the outermost insulating layer have a predetermined terminal pattern. As a result, unlike the conventional fabrication process A, it is possible to prevent an adhesive from flowing when the insulating layer is bonded to the film-like wiring substrate, and prevent an etching solution from flowing at the time of formation of an innerlayer wiring pattern in the conductive layer. This helps prevent contamination of the terminal portion, and hence poor connection of the terminal portion.

Also, unlike the conventional fabrication process B, it is possible to prevent the rigid layer from sticking to the conductive layer having a terminal pattern. This makes it possible to strip off the conductive layer having a terminal pattern from the rigid layer without causing damage or deformation. This helps maintain the terminal pattern of the conductive layer in good condition, making it possible to prevent poor connection of the terminal portion when electrically connecting the terminal portion to the connector.

In addition, since the insulating layer included in the terminal portion is formed of the same material as that for the rigid layer, the terminal portion has greater rigidity than the flexible portion. As a result, unlike the conventional example in which the terminal portion formed on the film-like wiring substrate needs to be reinforced with a reinforcing sheet, the insulating layer serves as a reinforcing sheet. This eliminates the need for a step of performing position adjustment and the like for forming an extra reinforcing sheet, making it possible to connect the terminal portion to the connector more easily.

According to the present invention, the terminal portion is formed by forming a plurality of insulating layers, and the conductive layer having a terminal pattern is formed on the surface of the outermost insulating layer. This makes it possible to change the height (thickness) of the terminal portion according to the size of the connector by changing the number of insulating layers to be formed. As a result, it is possible to connect the terminal portion to the connector more easily. In addition, since the conductive layer is formed on the surface of the outermost insulating layer, it is possible to connect the conductive layer to the connector no matter how many insulating layers are formed.

According to the present invention, the presence of the shielding layer makes it possible to form a terminal portion of high quality. For example, with the structure as described above, it is possible to prevent signal degradation caused by external noise, or it is possible to stabilize a signal transmitted via a ground plane and thereby achieve high-quality signal transmission.

According to the present invention, in the multilayer printed wiring board, the flexible portion is constructed with the film-like wiring substrate, and the rigid portion is constructed by forming, in a predetermined region of the film-like wiring substrate, a wiring layer having a predetermined wiring pattern and the rigid layer. On one of the surfaces of the film-like wiring substrate, the number of insulating layers of the terminal portion is equal to the number of rigid layers of the rigid portion.

As a result, on one of the surfaces of the film-like wiring substrate, the height of the rigid portion in the thickness direction is nearly equal to the height of the terminal portion in the thickness direction. This makes it possible to perform the formation of the conductive layer disposed on the outermost layer of the terminal portion concurrently with the formation of the wiring layer disposed on the outermost layer of the rigid portion. As described above, since the rigid portion and the terminal portion can be formed at the same time, it is possible to prevent contamination, damage, and deformation of the conductive layer more effectively, and hence poor connection of the terminal portion.

According to the present invention, the insulating layer of the terminal portion is formed in a region of an end portion of the film-like wiring substrate, and at least part of the insulating layer of the terminal portion is made to project from an edge of the film-like wiring substrate as seen in a plan view. The multilayer printed wiring board is formed into its final shape by cutting, in the thickness direction, a multilayered body having the insulating layer and the wiring layer formed one on top of another on the film-like wiring substrate. The multilayered body is obtained by forming the insulating layer having rigidity on both surfaces of a film-like wiring substrate formed of a thin material having flexibility. Here, in the conventional example, cutting different materials having different properties at the same time with a die or the like leaves burrs.

However, by making part of the insulating layer having the conductive layer of the terminal portion on the upper surface thereof project from the edge of the film-like wiring substrate as seen in a plan view, the edge portion of the terminal portion is formed of the insulating layer having rigidity. As a result, it is possible to form the terminal portion without cutting the film-like wiring substrate when forming the multilayer printed wiring board into its final shape. This helps prevent the occurrence of burrs, and hence poor connection of the terminal portion more effectively.

According to the present invention, the method for fabricating the multilayer printed wiring board is provided with: a step of forming the insulating layer and the conductive layer in the first and second regions located at a predetermined distance from each other on the film-like wiring substrate, the insulating layer including an outermost insulating layer having the conductive layer formed thereon; a step of forming the terminal portion including the conductive layer by partially removing the conductive layer formed on the outermost insulating layer so as to make the conductive layer have a predetermined terminal pattern in the first region, and electrically connecting the conductive layer having the terminal pattern to the film-like wiring substrate; and a step of forming the circuit portion by partially removing the conductive layer located in the second region so as to make the conductive layer have a predetermined wiring pattern, the circuit portion including the conductive layer having the predetermined wiring pattern.

As a result, it is possible to form the terminal portion after forming the insulating layer and the conductive layer on the film-like wiring substrate. This makes it possible to prevent an adhesive from flowing when the insulating layer is bonded to the film-like wiring substrate, and to prevent an etching solution from flowing when the conductive layer is partially removed so as to form a wiring pattern therein. This helps prevent contamination of the conductive layer having a terminal pattern and maintain the terminal portion in good condition, making it possible to prevent poor connection between the terminal portion and the connector.

According to the present invention, at the time of fabrication of the multilayer printed wiring board by using a step of forming the insulating layer and the conductive layer almost all over at least one of the surfaces of the film-like wiring substrate and a step of removing part of the insulating layer and the conductive layer, the conductive layer of the terminal portion, the conductive layer having a terminal pattern, is formed on the outermost insulating layer located in the first region. As a result, even when the film-like wiring substrate and the insulating layer stick to each other at the time of formation of the insulating layer and the conductive layer, the insulating layer does not stick to the conductive layer having a terminal pattern. This helps prevent damage and deformation of the conductive layer having a terminal pattern when the insulating layer is stripped off from the film-like wiring substrate, and hence poor connection between the terminal portion and the connector.

### BRIEF DESCRIPTION OF THE DRAWINGS

FIG. 1 is a perspective view of a multilayer printed wiring board according to a first embodiment of the invention in its entirety;

FIG. 2 is an enlarged, exploded perspective view of the terminal portion of the multilayer printed wiring board according to the first embodiment of the invention;

FIG. 3 is a plan view of the multilayer printed wiring board according to the first embodiment of the invention;

FIG. 4 is a perspective view showing a state in which the multilayer printed wiring board according to the first embodiment of the invention is connected to an external connector;

FIG. 5 is a sectional view of an example of the multilayer printed wiring board according to the first embodiment of the invention, the multilayer printed wiring board having a shielding layer formed therein;

FIG. 6 is a sectional view of another example of the multilayer printed wiring board according to the first embodiment of the invention, the multilayer printed wiring board having a shielding layer formed therein;

FIG. 7 is a sectional view showing a fabrication process of the multilayer printed wiring board according to the first embodiment of the invention;

FIG. 8 is a sectional view showing a fabrication process of the multilayer printed wiring board according to the first embodiment of the invention;

FIG. 9 is a sectional view showing a fabrication process of the multilayer printed wiring board according to the first embodiment of the invention;

FIG. 10 is a sectional view showing a fabrication process of the multilayer printed wiring board according to the first embodiment of the invention;

FIG. 11 is a sectional view showing a fabrication process of the multilayer printed wiring board according to the first embodiment of the invention;

FIG. 12 is a sectional view showing a fabrication process of the multilayer printed wiring board according to the first embodiment of the invention;

FIG. 13 is a sectional view showing a fabrication process of the multilayer printed wiring board according to the first embodiment of the invention;

FIG. 14 is a perspective view of a multilayer printed wiring board according to a second embodiment of the invention in its entirety;

FIG. 15 is a sectional view of the multilayer printed wiring board according to the second embodiment of the invention;

FIG. 16 is a sectional view showing a fabrication process of the multilayer printed wiring board according to the second embodiment of the invention;

FIG. 17 is a sectional view showing a fabrication process of the multilayer printed wiring board according to the second embodiment of the invention;

FIG. 18 is a sectional view showing a fabrication process of the multilayer printed wiring board according to the second embodiment of the invention;

FIG. 19 is a perspective view of a multilayer printed wiring board according to a third embodiment of the invention in its entirety;

FIG. 20 is a plan view of the multilayer printed wiring board according to the third embodiment of the invention; and

FIG. 21 is a perspective view of a multilayer printed wiring board according to a fourth embodiment of the invention in its entirety.

### DETAILED DESCRIPTION OF PREFERRED EMBODIMENTS

Hereinafter, embodiments of the invention will be described.

### First Embodiment

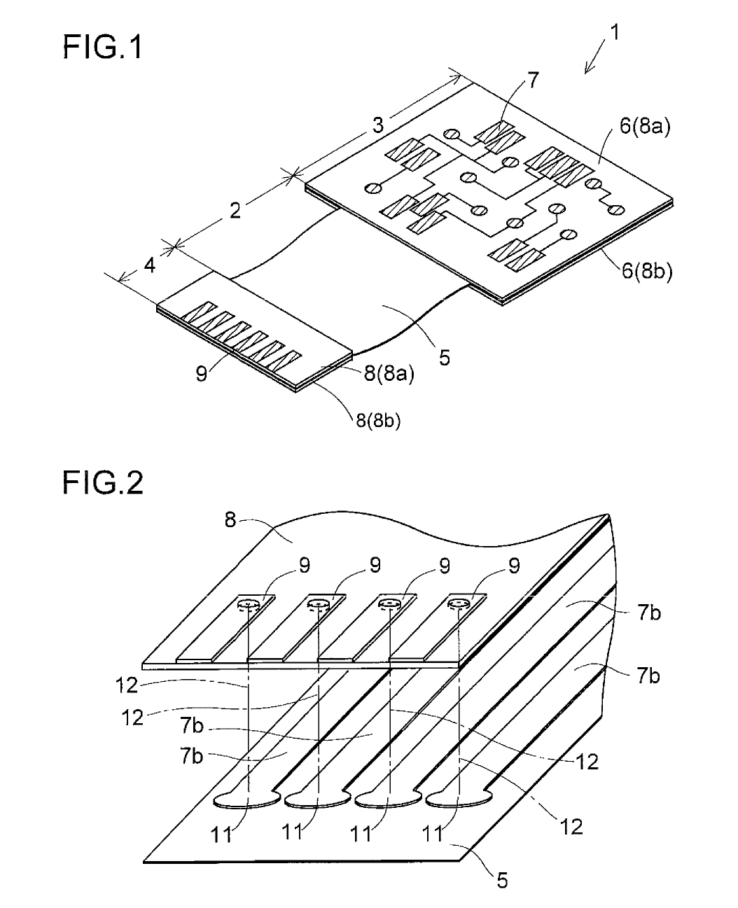

The structure of a multilayer printed wiring board according to a first embodiment of the invention is shown in FIGS. 1 to 6. A description will be given of a multilayer printed wiring board having four conductor layers in total and including a terminal portion having two conductor layers. However, the number of conductor layers formed is not limited to those described above; any number of conductor layers may be formed. The invention is suitable for use in a multilayer printed wiring board of any other type so long as it is provided with a terminal portion.

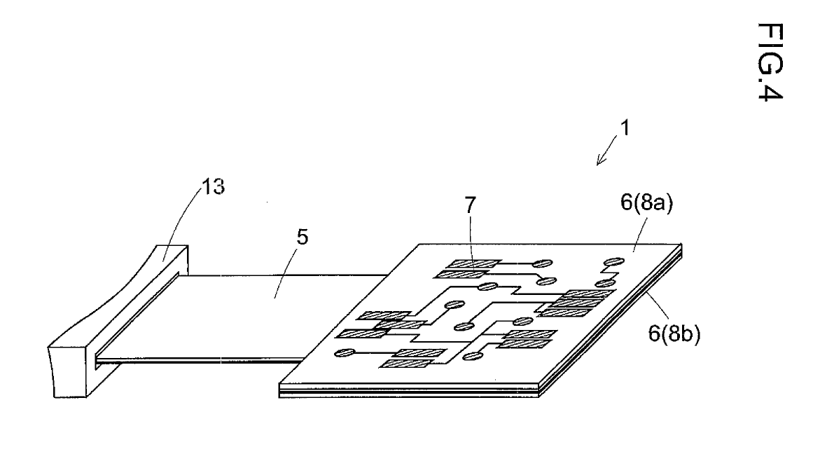

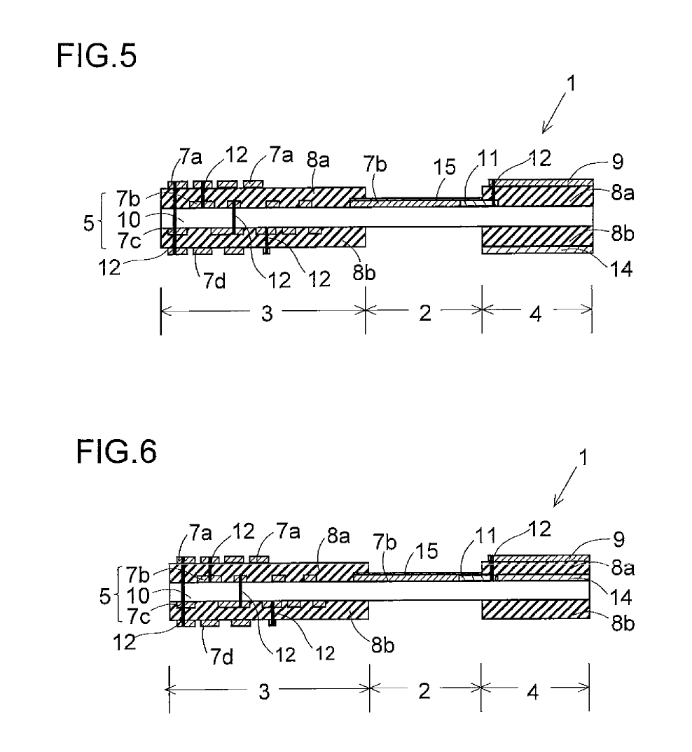

A multilayer printed wiring board 1 of the first embodiment is constructed as a so-called rigid-flexible wiring board. Specifically, as shown in FIG. 1, the multilayer printed wiring board 1 is composed of a flexible portion 2, a rigid portion 3, and a terminal portion 4. The flexible portion 2 is constructed as a flexible printed wiring board 5 formed of a thin material. The rigid portion 3 is constructed by forming a rigid layer 6 (insulating layers 8a and 8b) and a wiring layer 7 (7a to 7d; see FIGS. 5 and 6) having a predetermined wiring pattern on both surfaces of the flexible printed wiring board 5, the rigid layer 6 and the wiring layer 7 being formed one on top of another in part of each surface by using an adhesive, a hot press, and the like. The terminal portion 4 is constructed by forming an insulating layer 8 (8a and 8b) and a conductive layer 9 formed on the uppermost surface of the insulating layer 8a, the conductive layer 9 having a predetermined terminal pattern, on both surfaces of the flexible printed wiring board 5 in an end portion thereof. It is to be noted that the flexible printed wiring board 5 is an example of a “film-like wiring substrate” of the present invention.

The flexible printed wiring board 5 is constructed with a base film 10 formed of an insulating resin film such as a polyimide, polyether ketone, or liquid crystal polymer, the base film 10 having a wiring layer 7b formed on both or one surface thereof, the wiring layer 7b having a predetermined wiring pattern and formed of metallic foil (copper layer). As shown in FIG. 2, part of the wiring layer 7b disposed on the flexible printed wiring board 5 extends into a region where the conductive layer 9 formed on the surface of the insulating layer 8a is disposed. At an end portion of the wiring layer 7b on the side of the terminal portion 4, a land portion 11 formed of a copper layer is formed integrally with the wiring layer 7b.

The rigid layer 6 disposed in the rigid portion 3 and the insulating layer 8 disposed in the terminal portion 4 are formed of the same insulating material such as glass epoxy or polyimide.

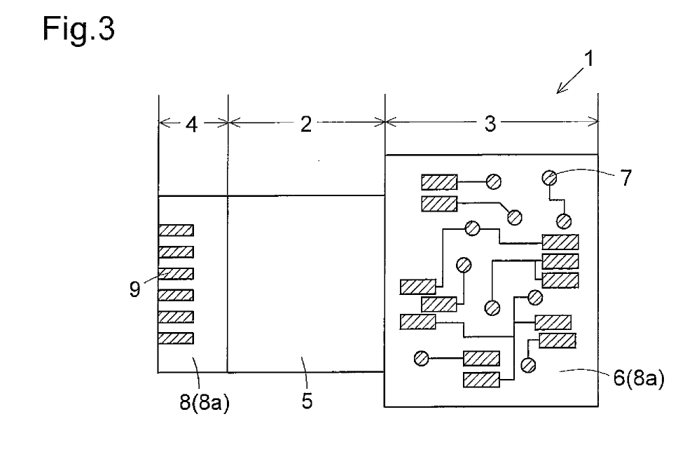

As shown in FIG. 3, the wiring layer 7 disposed in the rigid portion 3 and the conductive layer 9 disposed in the terminal portion 4 are each formed of a copper layer. As shown in FIG. 2, the conductive layer 9 has formed therein a through hole (connecting portion) 12 for electrically connecting the land portion 11 and the conductive layer 9, the through hole 12 being formed in the vertical direction in a position of the conductive layer 9 away from the edge of the insulating layer 8a. The through hole 12 is plated. It is to be noted that the through hole 12 is an example of a “connecting portion” of the present invention.

As will be understood from an example shown in FIG. 4, the terminal portion 4 is inserted into a connector 13 provided in the other wiring board, an electronic device, an electronic part, or the like, such that the conductive layer 9 of the terminal portion 4 is electrically connected to a contact (not shown) provided in the connector 13. Alternatively, though not illustrated, the terminal portion 4 is brought into contact with a terminal portion provided in the other wiring board, the electronic device, the electronic part, or the like, such that connection with the other wiring board, the electronic device, the electronic part, or the like, is established.

In the multilayer printed wiring board 1 of the first embodiment, the terminal portion 4 may be provided with a shielding layer 14 formed of aluminum foil, conductive paste, or the like. As shown in FIGS. 5 and 6, the shielding layer 14 may be formed on the surface of the insulating layer 8b disposed on the lower surface of the flexible printed wiring board 5, or may be formed between the flexible printed wiring board 5 and the insulating layer 8a disposed on the upper surface of the flexible printed wiring board 5. The shielding layer 14 formed in the multilayer printed wiring board 1 of the first embodiment makes it possible to form a terminal portion of high quality. For example, with the structure as described above, it is possible to prevent signal degradation caused by external noise, or it is possible to stabilize a signal transmitted via a ground plane and thereby achieve high-quality signal transmission. In this case, the shielding layer 14 is located away from the land portion 11 disposed at the edge of the wiring layer 7b, and is electrically insulated therefrom.

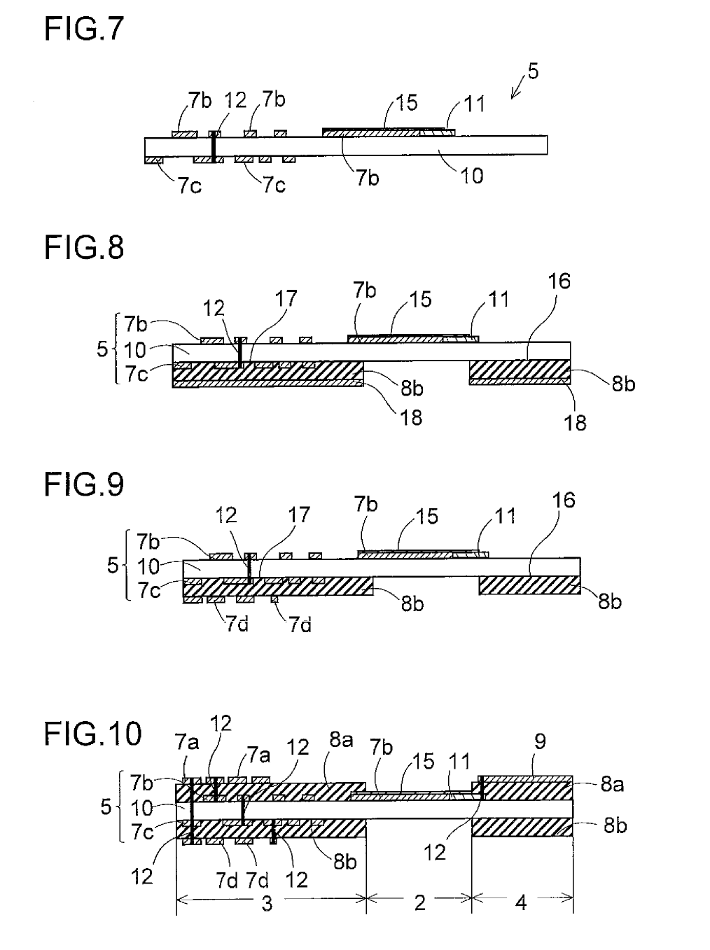

Next, a first fabrication method of the multilayer printed wiring board according to the first embodiment of the invention will be described with reference to FIGS. 7 to 10.

First, the flexible printed wiring board 5 is fabricated as follows. As shown in FIG. 7, the metallic foil (not shown), which is the copper foil, is formed on both surfaces of the base film 10. Then, the metallic foil disposed on the upper surface of the base film 10 and the metallic foil disposed on the lower surface thereof are subjected to photolithography and etching so as to become the wiring layer 7b (the conductive layer having a predetermined wiring pattern) and a wiring layer 7c, respectively. The land portion 11 is formed at an end portion of the wiring layer 7b on that side of the wiring layer 7b where the terminal portion 4 is formed. The wiring layer 7b and the wiring layer 7c are electrically connected via the through hole 12 formed in the base film 10. Thereafter, a coverlay film 15 is bonded by thermal compression to the upper surface of the wiring layer 7b formed in a region which will become the flexible portion 2 for the purpose of circuit protection, prevention of solder bridges, electrical insulation, enhancement of bending characteristics, and the like. The coverlay film 15 is formed of the same material as that for the base film 10. In this way, the flexible printed wiring board 5 is fabricated.

Next, as shown in FIG. 8, the insulating layer 8b having an opening in a predetermined region thereof and having metallic foil 18 formed on one face thereof is formed in a first region 16 and a second region 17 on the lower surface of the flexible printed wiring board 5 by using an adhesive, a hot press, and the like, such that a region of the flexible printed wiring board 5 which will become the flexible portion 2 is exposed. In this embodiment, the first region 16 is a region corresponding to one end portion of the flexible printed wiring board 5, the region in which the terminal portion 4 is disposed, and the second region 17 is a region corresponding to the other end portion of the flexible printed wiring board 5, the region in which the rigid portion 3 is disposed. It is to be noted that the metallic foil 18 is an example of the “conductive layer” of the present invention.

As shown in FIG. 9, the metallic foil 18 disposed in the second region 17 is partially removed so as to form a predetermined wiring pattern, and serves as a wiring layer 7d. The metallic foil 18 disposed in the first region 16 is removed, such that the insulating layer 8b is exposed.

Then, as shown in FIG. 10, the insulating layer 8a having an opening in a predetermined region thereof and having the metallic foil 18 formed on one face thereof is formed in the first region 16 and the second region 17 on the upper surface of the flexible printed wiring board 5 by using an adhesive, a hot press, and the like. As a result, a portion of the flexible printed wiring board 5 which will become the flexible portion 2 is exposed. The metallic foil 18 disposed in the second region 17 is partially removed so as to form a predetermined wiring pattern, and serves as a wiring layer 7a, and the metallic foil 18 disposed in the first region 16 is partially removed so as to form a predetermined terminal pattern, and serves as the conductive layer 9. As just described, the wiring layer 7a and the conductive layer 9 are formed in the same process.

Finally, the through holes 12 for electrically connecting between the wiring layers and between the wiring layer 7b and the conductive layer 9 are formed in the insulating layers 8a and 8b. Each through hole 12 is formed by using a laser or the like, and the inside thereof is coated with plating. If necessary, formation of a solder resist, marking of symbols, plating of the conductive layer 9, and the like, are performed. In this way, the multilayer printed wiring board 1 provided with the terminal portion 4, the flexible portion 2, and the rigid portion 3 is fabricated.

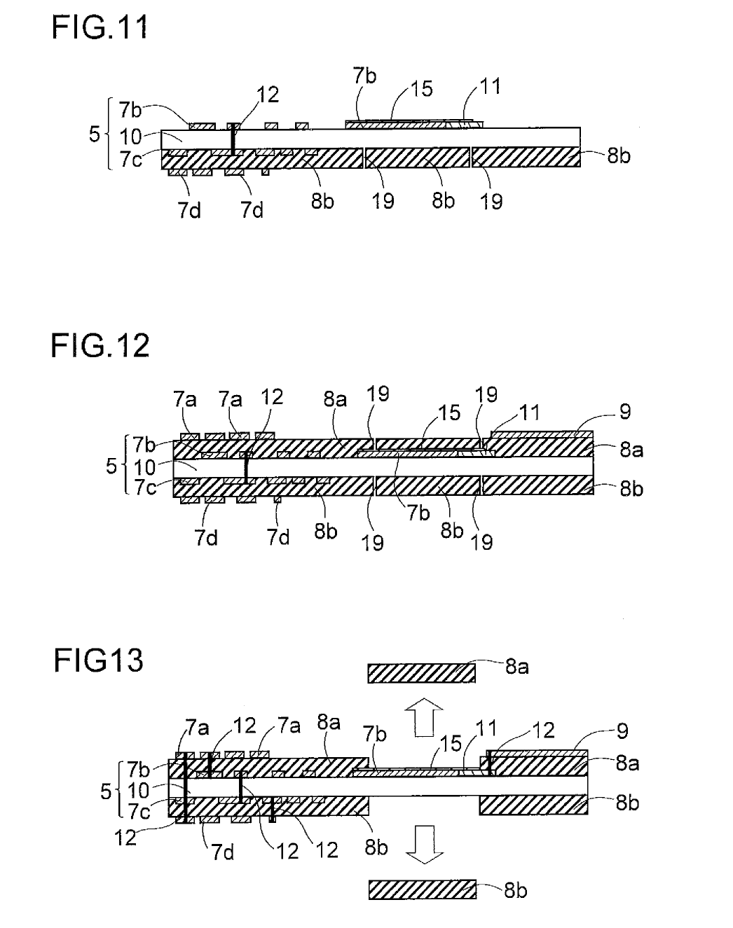

Next, a second fabrication method of the multilayer printed wiring board according to the first embodiment of the invention will be described with reference to FIGS. 11 to 13

First, the flexible printed wiring board 5 is fabricated. This fabrication process is the same as that of the first fabrication method, and therefore the description thereof will be omitted.

Next, as shown in FIG. 11, the insulating layer 8b having the metallic foil 18 formed on one face thereof is formed almost all over the lower surface of the flexible printed wiring board 5 by using an adhesive, a hot press, and the like. At this point, slits 19 are formed, one for each of the first region 16 and the second region 17 in the insulating layer 8b, so as to mark the boundary between the first region 16 and the other region and the boundary between the second region 17 and the other region. The metallic foil 18 disposed on the lowermost surface of the second region 17 is partially removed so as to form the wiring layer 7d, and the metallic foil 18 disposed on the lowermost surface of the first region 16 is removed, such that the insulating layer 8b is exposed.

As shown in FIG. 12, the insulating layer 8a having the metallic foil 18 on one face thereof is formed almost all over the upper surface of the flexible printed wiring board 5. At this point, as is the case with the insulating layer 8b disposed on the lower surface of the flexible printed wiring board 5, the slits 19 are formed, one for each of the first region 16 and the second region 17 in the insulating layer 8a disposed on the upper surface of the flexible printed wiring board 5, so as to mark the boundary between the first region 16 and the other region and the boundary between the second region 17 and the other region. The metallic foil 18 disposed on the uppermost surface of the second region 17 is partially removed so as to form the wiring layer 7a, and the metallic foil 18 disposed on the uppermost surface of the first region 16 is partially removed so as to form the conductive layer 9. As just described, the wiring layer 7a and the conductive layer 9 are formed in the same process.

Finally, as shown in FIG. 13, the through holes 12 for electrically connecting the wiring layers 7 and between the wiring layer 7b and the conductive layer 9 are formed in the insulating layers 8a and 8b. If necessary, formation of a solder resist, marking of symbols, plating of the conductive layer 9, and the like, are performed. Then, part of the insulating layer 8a and part of the insulating layer 8b are stripped off by reference to the slits 19, such that the flexible printed wiring board 5 is exposed. In this way, the multilayer printed wiring board 1 provided with the terminal portion 4, the flexible portion 2, and the rigid portion 3 is fabricated. It is to be understood that the insulating layers 8a and 8b may be stripped off in any other way than is specifically described above. For example, it is also possible to cut the insulating layers 8a and 8b by using an excimer laser or the like, or perform half blanking so as to cut only the insulating layers 8a and 8b.

### Second Embodiment

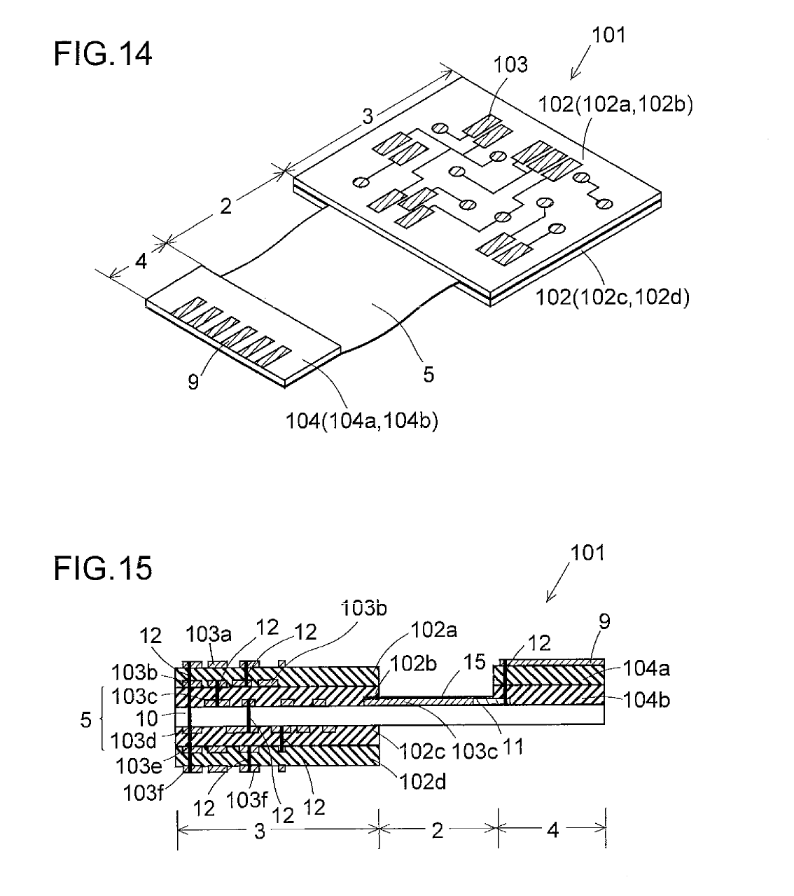

A multilayer printed wiring board 101 according to a second embodiment of the invention is shown in FIGS. 14 and 15. For convenience of explanation, such portions as find their counterparts in the first embodiment shown in FIGS. 1 to 13 are identified with the same reference characters, and their explanations will be omitted. A description will be given of a multilayer printed wiring board having six conductor layers in total and including a terminal portion having two conductor layers. However, the number of conductor layers formed is not limited to those described above; any number of conductor layers may be formed. The invention is suitable for use in a multilayer printed wiring board of any other type so long as it is provided with a terminal portion.

As shown in FIG. 14, the multilayer printed wiring board 101 of the second embodiment is composed of the flexible portion 2, the rigid portion 3, and the terminal portion 4. The flexible portion 2 is constructed as the flexible printed wiring board 5. The rigid portion 3 is constructed by forming a plurality of rigid layers 102 and a plurality of wiring layers 103, each having a predetermined wiring pattern, on part of both surfaces of the flexible printed wiring board 5, the rigid layers 102 and the wiring layers 103 being formed one on top of another so as to form alternating layers thereof, by using an adhesive, a hot press, and the like. The terminal portion 4 is constructed by forming a plurality of insulating layers 104 on the upper surface of the flexible printed wiring board 5 in an end portion thereof and forming the conductive layer 9 on the surface of the uppermost insulating layer 104. In other respects, the multilayer printed wiring board 101 of this embodiment has the same structure as that of the first embodiment. Incidentally, the plurality of insulating layers 104 (or rigid layers 102) and wiring layers 103 are not shown in FIG. 14.

As a result of the plurality of insulating layers 104 being formed in the terminal portion 4, the multilayer printed wiring board 101 according to the second embodiment of the invention makes it possible to change the height (thickness) of the terminal portion 4 according to the size of the connector 13. This makes it possible to connect the terminal portion 4 to the connector 13 more easily. In addition, as a result of the conductive layer 9 being formed on the surface of the uppermost layer of the plurality of insulating layers 104, it is possible to connect the conductive layer 9 to the connector no matter how many insulating layers 104 are formed.

The structure of the rigid portion 3 of the multilayer printed wiring board 101 according to the second embodiment of the invention will be described in detail with reference to FIG. 15. As shown in FIG. 15, the rigid portion 3 is formed as follows. First, a wiring layer 103c is disposed on the upper surface of the flexible printed wiring board 5. Then, on part of the upper surface of the wiring layer 103c, a second rigid layer 102b, a wiring layer 103b, a first rigid layer 102a, and a wiring layer 103a are formed in the order mentioned. Similarly, a wiring layer 103d is disposed on the lower surface of the flexible printed wiring board 5. Then, on part of the lower surface of the wiring layer 103d, a third rigid layer 102c, a wiring layer 103e, a fourth rigid layer 102d, and a wiring layer 103f are formed in this order.

As shown in FIG. 15, the terminal portion 4 has the following layers formed one on top of another in the order mentioned on the upper surface of the flexible printed wiring board 5 in an end portion thereof: an insulating layer 104b, an insulating layer 104a, and a conductive layer 9. Here, the insulating layer 104b is disposed so as to overlap with the land portion 11 formed integrally with the wiring layer 103c.

The through holes 12 are formed in the rigid layers 102 and the insulating layers 104 for electrically connecting between the wiring layers 103 in the rigid portion 3 and between the land portion 11 and the conductive layer 9 in the terminal portion 4. As shown in FIG. 15, in the multilayer printed wiring board 101 of the second embodiment, on the upper surface of the flexible printed wiring board 5, the number of insulating layers 104 in the terminal portion 4 is equal to the number of rigid layers 102 in the rigid portion 3. As a result, on the upper surface of the flexible printed wiring board 5, the height of the rigid portion 3 in the thickness direction is nearly equal to the height of the terminal portion 4 in the thickness direction. In addition, it is possible to perform the formation of the conductive layer 9 disposed on the outermost layer of the terminal portion 4 concurrently with the formation of the wiring layer 103 disposed on the outermost layer of the rigid portion 3. This helps prevent contamination, damage, and deformation of the conductive layer 9 more effectively that would occur during the fabrication of the multilayer printed wiring board, and hence poor connection of the terminal portion 4.

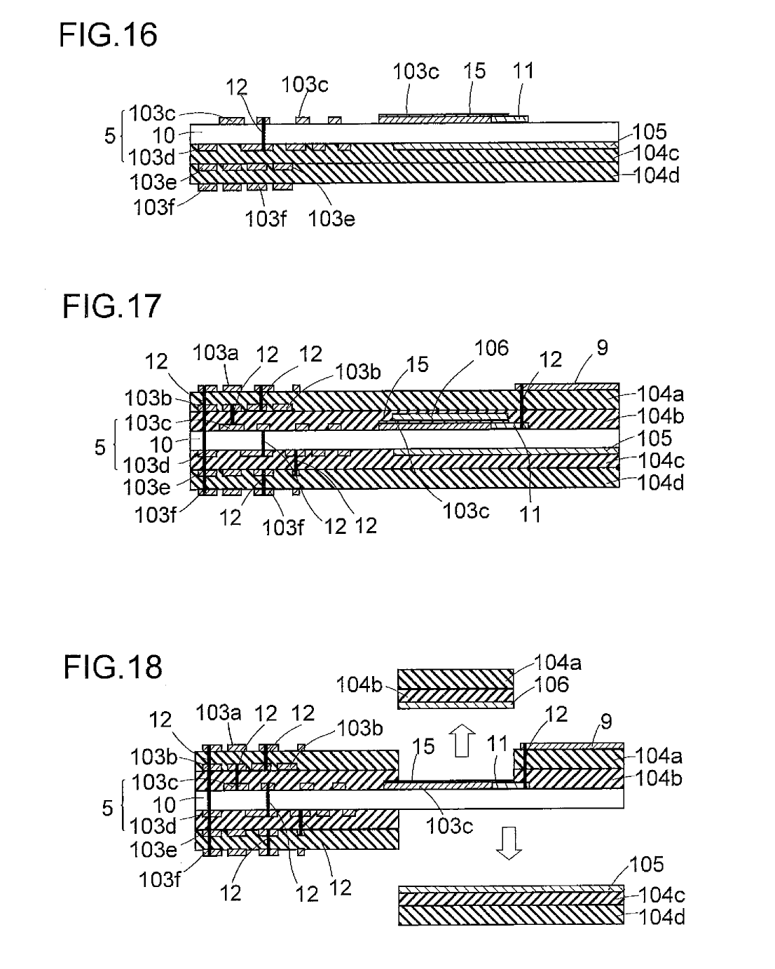

Next, a fabrication method of the multilayer printed wiring board according to the second embodiment of the invention is shown in FIGS. 16 to 18.

The multilayer printed wiring board 101 of the second embodiment may be fabricated by using the first fabrication method of the first embodiment. That is, the multilayer printed wiring board 101 may be fabricated by forming the insulating layers 104 (or the rigid layers 102), each having an opening in a region which will become the flexible portion 2, on the flexible printed wiring board 5, and then partially removing the metallic foil 18 so as to form a predetermined terminal pattern and a predetermined wiring pattern. Alternatively, the second fabrication method of the first embodiment may be used. That is, the multilayer printed wiring board 101 may be fabricated by forming the insulating layers 104 (or the rigid layers 102) all over the flexible printed wiring board 5, and then removing a region of the flexible printed wiring board 5 which will become the flexible portion 2.

In a case where the second fabrication method of the first embodiment is used, the multilayer printed wiring board 101 may be fabricated as follows.

First, as shown in FIG. 16, an insulating layer 104c having the metallic foil on one face thereof is formed almost all over the lower surface of the flexible printed wiring board 5. At this point, a separating film 105 is laid between the flexible printed wiring board 5 and the insulating layer 104c in a region (in this embodiment, a region which will become the flexible portion 2 and the terminal portion 4) to be exposed in the later process. The separating film 105 is formed of a polyimide film, aluminum foil, copper foil, or the like. Then, the metallic foil is partially removed so as to form a predetermined wiring pattern by using photolithography and etching, whereby the wiring layer 103e is formed. Thereafter, an insulating layer 104d having the metallic foil on one face thereof is formed in the lower surface of the wiring layer 103e, and the metallic foil is partially removed so as to form the wiring layer 103f.

Next, as shown in FIG. 17, the insulating layer 104b having the metallic foil on one face thereof is formed almost all over the upper surface of the flexible printed wiring board 5. At this point, a separating film 106 is laid between the flexible printed wiring board 5 and the insulating layer 104b in a region (in this embodiment, a region which will become the flexible portion 2) in which the flexible printed wiring board 5 is exposed in the later process. Then, the metallic foil formed on the insulating layer 104b is partially removed so as to form the wiring layer 103b. Thereafter, the insulating layer 104a having the metallic foil on one face thereof is formed on the upper surface of the wiring layer 103b. The metallic foil formed on the insulating layer 104a is partially removed so as to form the wiring layer 103a and the conductive layer 9. Then, the through holes 12 are formed in the insulating layers 104 for electrically connecting between the conductive layer 9 and the land portion 11 and between the wiring layers 103.

Finally, as shown in FIG. 18, the multilayer printed wiring board 101 is obtained by removing the insulating layer 104 and the metallic foil formed in the regions in which the separating film 105 and the separating film 106 are disposed. As a result of the separating films 105 and 106 being disposed, it is possible to remove the insulating layer 104 and the metallic foil without causing damage to the flexible printed wiring board 5. This makes it possible to fabricate the multilayer printed wiring board 101 more easily.

### Third Embodiment

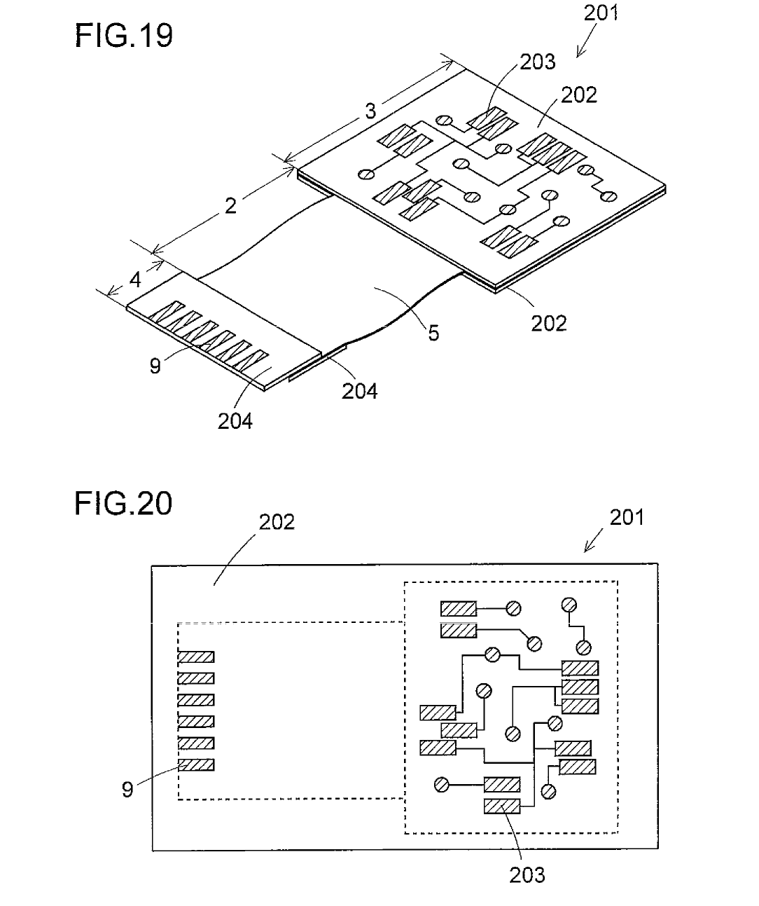

A multilayer printed wiring board according to a third embodiment of the invention is shown in FIGS. 19 and 20. For convenience of explanation, such portions as find their counterparts in the first and second embodiments shown in FIGS. 1 to 18 are identified with the same reference characters, and their explanations will be omitted.

As shown in FIG. 19, a multilayer printed wiring board 201 of the third embodiment is composed of the flexible portion 2, the rigid portion 3, and the terminal portion 4. The flexible portion 2 is constructed as the flexible printed wiring board 5. The rigid portion 3 is constructed by forming a rigid layer 202 and a wiring layer 203 on part of both surfaces of the flexible printed wiring board 5. The terminal portion 4 is constructed by forming an insulating layer 204 on both surfaces of the flexible printed wiring board 5 in an end portion thereof, such that part of the insulating layer 204 having the conductive layer 9 on the upper surface thereof projects from the edge of the flexible printed wiring board 5 as seen in a plan view. In other respects, the structure of the third embodiment is the same as those of the first and second embodiments.

As shown in FIG. 20, the multilayer printed wiring board 201 is formed into its final shape by cutting, along dotted lines in the thickness direction, a multilayered body having the insulating layer 204 and the wiring layer 203 formed one on top of another on the flexible printed wiring board 5. The multilayered body is obtained by forming the insulating layer 204 having rigidity on both surfaces of the flexible printed wiring board 5 formed of a thin material having flexibility. Thus, cutting different materials having different properties at the same time with a die or the like leaves burrs. However, by making part of the insulating layer 204 having the conductive layer 9 of the terminal portion 4 on the upper surface thereof project from the edge of the flexible printed wiring board 5 as seen in a plan view, the edge portion of the terminal portion 4 is formed of a material having rigidity.

As a result, it is possible to form the terminal portion 4 without cutting the flexible printed wiring board 5 when forming the multilayer printed wiring board 201 into its final shape. This helps prevent the occurrence of burrs, and hence poor connection of the terminal portion 4 more effectively.

The multilayer printed wiring board of the third embodiment may be fabricated by using the first fabrication method of the first embodiment. That is, the multilayer printed wiring board 201 may be fabricated by forming, on the flexible printed wiring board 5, the insulating layer 204 (or the rigid layer 202) having an opening in a region which will become the flexible portion 2, and then partially removing the metallic foil so as to form a predetermined terminal pattern and a predetermined wiring pattern. Alternatively, the second fabrication method of the first embodiment may be used. That is, the multilayer printed wiring board 201 may be fabricated by forming the insulating layer 204 (or the rigid layer 202) all over the flexible printed wiring board 5, and then removing a region which will become the flexible portion 2.

In this case, in either of the first fabrication method and the second fabrication method, in an end portion of the upper surface of the flexible printed wiring board 5, part of the insulating layer 204 having the conductive layer 9 on the upper surface thereof is made to project from the edge of the flexible printed wiring board 5.

### Fourth Embodiment

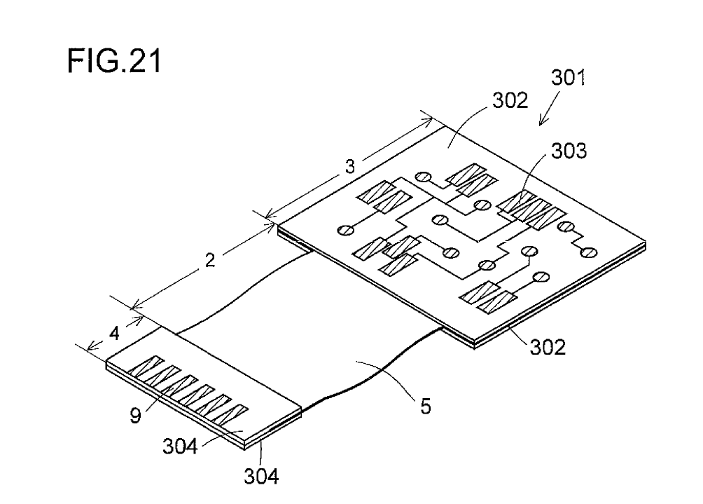

A multilayer printed wiring board according to a fourth embodiment of the invention is shown in FIG. 21. For convenience of explanation, such portions as find their counterparts in the first, second, and third embodiments shown in FIGS. 1 to 20 are identified with the same reference characters, and their explanations will be omitted.

As shown in FIG. 21, a multilayer printed wiring board 301 of the fourth embodiment is composed of the flexible portion 2, the rigid portion 3, and the terminal portion 4. The flexible portion 2 is constructed as the flexible printed wiring board 5. The rigid portion 3 is constructed by forming a rigid layer 302 and a wiring layer 303 on part of both surfaces of the flexible printed wiring board 5. The terminal portion 4 is constructed by forming insulating layers 304 on both surfaces of the flexible printed wiring board 5 in an end portion thereof, such that part of the insulating layers 304 projects from the edge of the flexible printed wiring board 5 as seen in a plan view. In other respects, the structure of the fourth embodiment is the same as those of the first, second, and third embodiments.

The insulating layers 304 disposed in the terminal portion 4 are bonded together in the part thereof projecting from the flexible printed wiring board 5 by an adhesive, a hot press, and the like. As a result, the edge portion of the terminal portion 4 is formed of a material having rigidity. This ensures that, no matter how many insulating layers 304 are formed, the edge portion of the terminal portion 4 does not include the flexible printed wiring board 5. This helps prevent the occurrence of burrs of the terminal portion 4 when forming the multilayer printed wiring board 301 into its final shape, and hence poor connection of the terminal portion 4 more effectively.

The multilayer printed wiring board 301 of the fourth embodiment may be fabricated by using the first fabrication method of the first embodiment. That is, the multilayer printed wiring board 301 may be fabricated by forming, on the flexible printed wiring board 5, the insulating layers 304 (or the rigid layers 302) having an opening in a region which will become the flexible portion 2, and then partially removing the metallic foil so as to form a predetermined terminal pattern and a predetermined wiring pattern. Alternatively, the second fabrication method of the first embodiment may be used. That is, the multilayer printed wiring board 301 may be fabricated by forming the insulating layers 304 (or the rigid layers 302) all over the flexible printed wiring board 5, and then removing a region which will become the flexible portion 2.

In this case, in either of the first fabrication method and the second fabrication method, part of the insulating layers 304 disposed in the terminal portion 4 is made to project from the edge of the flexible printed wiring board 5, and the insulating layers 304 are bonded together in the part thereof projecting from the flexible printed wiring board 5 by an adhesive, a hot press, and the like.

It should be understood that the embodiments disclosed herein are in all respects merely examples of and are in no way meant to limit how the invention is carried out. The scope of the invention should be determined not with reference to the explanations of the embodiments described above but in view of the scope of the appended claims, and should be understood to include any modifications within the significance and range equivalent to those of the claims. For example, the first to fourth embodiments deal with cases in which the copper metallic foil is used for forming the copper layer (metal layer), the wiring layer, and the conductive layer; however, it is also possible to use metallic foil other than copper foil or any other conductive material for forming the copper layer (metal layer), the wiring layer, and the conductive layer.

In the multilayer printed wiring boards of the third and fourth embodiments, a plurality of wiring layers and a plurality of rigid layers may be formed in the rigid portion, and a plurality of insulating layers may be formed in the terminal portion.

The multilayer printed wiring boards of the second to fourth embodiments may be provided with the shielding layer of the first embodiment.

According to the multilayer printed wiring boards of the first to fourth embodiments of the invention, the terminal portion is so formed as to include the insulating layer and the conductive layer. This makes it possible to form the terminal portion by making, after the formation the insulating layer and the conductive layer, the conductive layer formed on the outermost insulating layer have a predetermined terminal pattern. As a result, in the first fabrication method, it is possible to prevent an adhesive from flowing at the time of formation of the insulating layer, and prevent an etching solution from flowing at the time of formation of an innerlayer wiring pattern in the metallic foil. This helps prevent contamination of the conductive layer, and hence poor connection of the terminal portion.

In addition, in the second fabrication method, it is possible to prevent damage or deformation of the conductive layer that would occur when the conductive layer is stripped off from the rigid layer (insulating layer). This helps maintain the terminal pattern of the conductive layer in good condition, making it possible to prevent poor connection of the terminal portion when electrically connecting between the terminal portion and the connector.

Furthermore, since the terminal portion includes the insulating layer and the conductive layer, and the insulating layer is formed of the same material as that for the rigid layer, the terminal portion has greater rigidity than the flexible portion. As a result, unlike the conventional example in which the terminal portion formed on the flexible printed wiring board needs to be reinforced with a reinforcing sheet, the insulating layer serves as a reinforcing sheet. This eliminates the need for a step of performing position adjustment and the like for forming an extra reinforcing sheet making it possible to connect the terminal portion to the connector more easily.

What is claimed is:

1. A multilayer printed wiring board, comprising:
a flexible portion having flexibility, the flexible portion that can be bent when used;
a rigid portion formed continuously with the flexible portion, the rigid portion having greater rigidity than the flexible portion; and
a terminal portion formed continuously with the flexible portion at an end portion of the flexible portion,
wherein the rigid portion comprises a rigid layer having insulation properties,
wherein the terminal portion comprises an insulating layer formed of a same material as a material for the rigid layer, the insulating layer having a conductive layer formed on a surface thereof, the conductive layer having a predetermined terminal pattern and serving as a connecting terminal.

2. The multilayer printed wiring board of claim 1,
wherein the terminal portion is constructed as a connecting terminal portion of an insertion type.

3. The multilayer printed wiring board of claim 1,
wherein the terminal portion comprises a connecting portion for electrically connecting between the flexible portion and the conductive layer.

4. The multilayer printed wiring board of claim 1,
wherein the insulating layer of the terminal portion comprises a plurality of insulating layers,
wherein the conductive layer having the predetermined terminal pattern is formed on a surface of an outermost layer of the plurality of insulating layers.

5. The multilayer printed wiring board of claim 1,
wherein the terminal portion further comprises a shielding layer.

6. The multilayer printed wiring board of claim 1,
wherein the flexible portion is constructed with a film-like wiring substrate,
wherein the rigid portion is constructed by forming, in a predetermined region of the film-like wiring substrate, a plurality of wiring layers, each having a predetermined wiring pattern, and the rigid layer comprising a plurality of rigid layers.

7. The multilayer printed wiring board of claim 6,
wherein, on one of surfaces of the film-like wiring substrate, the insulating layer of the terminal portion comprises a plurality of insulating layers, and a number of the insulating layers of the terminal portion is equal to a number of the rigid layers of the rigid portion.

8. The multilayer printed wiring board of claim 6,
wherein the insulating layer of the terminal portion is formed in a region of an end portion of the film-like wiring substrate,
wherein at least part of the insulating layer of the terminal portion is made to project from an edge of the film-like wiring substrate as seen in a plan view.

9. A method for fabricating a multilayer printed wiring boards the method comprising:
a step of forming an insulating layer and a conductive layer in a plurality of regions on a film-like wiring substrate, the plurality of regions being located at a predetermined distance from each other, the insulating layer comprising an outermost insulating layer having the conductive layer formed thereon; and
a step of forming a terminal portion including the conductive layer by partially removing the conductive layer formed on the outermost insulating layer so as to make the conductive layer have a predetermined terminal pattern in at least one of the plurality of regions, and electrically connecting the conductive layer having the predetermined terminal pattern to the film-like wiring substrate.

10. The fabrication method of claim 9,
wherein the plurality of regions include a first region and a second region,
wherein the step of forming the terminal portion includes a step of partially removing the conductive layer formed on the outermost insulating layer located in the first region so as to make the conductive layer have a predetermined terminal pattern, and a step of forming a connecting portion for electrically connecting between the conductive layer and the film-like wiring substrate,
wherein the fabrication method further comprises:
a step of forming a circuit portion by partially removing the conductive layer located in the second region so as to make the conductive layer have a predetermined wiring pattern, the circuit portion including the conductive layer having the predetermined wiring pattern.

11. The fabrication method of claim 9,
wherein the step of forming the insulating layer and the conductive layer includes a step of forming an insulating layer having an opening in a predetermined region and an conductive layer having an opening in a predetermined region on at least one of surfaces of the film-like wiring substrate.

12. The fabrication method of claim 9,
wherein the step of forming the insulating layer and the conductive layer includes a step of forming the insulating layer and the conductive layer almost all over at least one of surfaces of the film-like wiring substrate,
wherein the fabrication method further comprises:
a step of removing part of the insulating layer and the conductive layer.

13. The fabrication method of claim 12,
wherein the step of removing part of the insulating layer and the conductive layer includes a step of removing part of the insulating layer and the conductive layer forming the terminal portion.

14. The fabrication method of claim 9, further comprising:
a step of forming the multilayer printed wiring board into a final shape, such that the terminal portion is located in an end portion of the film-like wiring substrate as seen in a plan view.
